(19) United States
(12) Patent Application Publication
(10) Pub. No.: US 2026/0215291 A1
(43) Pub. Date: Jul. 23, 2026

(54) METHOD AND LEAD FRAME WITH DIE ATTACH FILM

(71) Applicant: Texas Instruments Incorporated, Dallas, TX (US)

(72) Inventors: Rongwei Zhang, Plano, TX (US); Enis Tuncer, Dallas, TX (US)

(21) Appl. No.: 19/033,128

(22) Filed: Jan. 21, 2025

(51) Int. Cl. H10W 70/40; H10W 70/04; H10W 72/00; H10W 72/30; H10W 90/00

(52) U.S. Cl. CPC H10W 70/417; H10W 70/042; H10W 70/456; H10W 72/01323; H10W 72/01361; H10W 72/01365; H10W 72/0198; H10W 72/07311; H10W 72/07338; H10W 72/354; H10W 90/736

(57) ABSTRACT

A method includes forming a die attach film (DAF) on select portions of a metal substrate and forming lead frame features in the metal substrate while the DAF is present. A lead frame includes a metal substrate having opposite first and second sides that extend in respective first and second planes of a first direction and an orthogonal second direction, and openings extending between the first and second sides of the metal substrate in respective unit areas arranged in rows along the first direction and columns along the second direction, the respective unit areas including a prospective lead, and a DAF extending on select portions of the second side of the metal substrate.

### BACKGROUND

Electrical isolation is a feature of many electronic devices such as integrated circuits. Non-conductive die attach film (DAF) can be used as an adhesive to attach a semiconductor die to a lead frame and achieve die isolation for electrical isolation devices. The DAF can be coated on the back side of a semiconductor wafer prior to wafer dicing, with the remaining DAF used to attach the separated semiconductor die onto an etched or stamped lead frame. However, saw or laser cutting during wafer dicing can produce silicon splinters or other conductive silicon debris which can be embedded into die attach film. The silicon splinters or debris embedded in the DAF can compromise the electrical isolation between the semiconductor die and the lead frame and lead to current leakage. Moreover, coefficient of thermal expansion (CTE) mismatch of the wafer and the DAF can cause wafer bowing or warpage where the wafer backside is coated with DAF, especially for thin wafers.

### SUMMARY

In one aspect, a method includes forming a die attach film on select portions of metal substrate and forming lead frame features in the metal substrate while the DAF is present.

In another aspect, a lead frame includes a metal substrate having opposite first and second sides that extend in respective first and second planes of a first direction and an orthogonal second direction, and openings extending between the first and second sides of the metal substrate in respective unit areas arranged in rows along the first direction and columns along the second direction, the respective unit areas including a prospective lead, and a die attach film extending on select portions of the second side of the metal substrate.

### BRIEF DESCRIPTION OF THE DRAWINGS

FIG. 1 is a partial sectional side elevation view of an electronic device with a semiconductor die attached to leads by a die attach film adhesive taken along line 1-1 of FIG. 1A.

FIG. 1A is a top plan view of the electronic device of FIG. 1.

FIG. 2 is a flow diagram of a method of fabricating an electronic device.

FIGS. 3-12 are partial sectional side elevation and top plan views of a lead frame and electronic devices undergoing fabrication processing according to the method of FIG. 2.

### DETAILED DESCRIPTION

In the drawings, like reference numerals refer to like elements throughout, and the various features are not necessarily drawn to scale. Also, the term "couple" or "couples" includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/- 10 percent of the stated value. One or more structures, features, aspects, components, etc., may be referred to herein as first, second, third, etc., such as first and second terminals, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

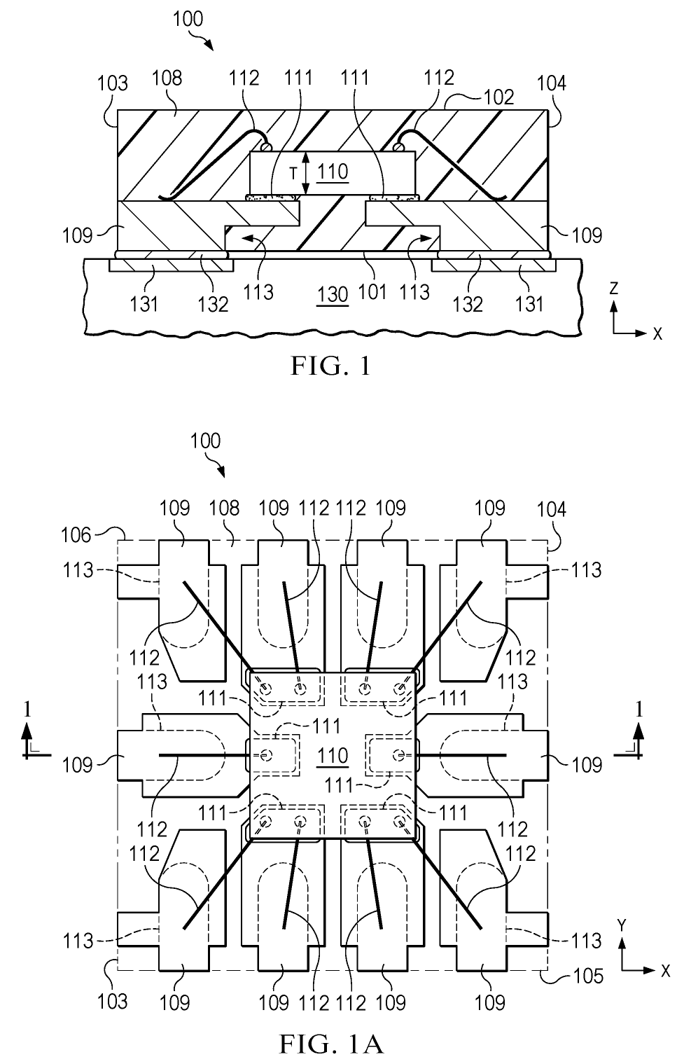

FIGS. 1 and 1A show a compact electronic device 100 with a semiconductor die 110 attached to internal surfaces of leads 109 by a die attach film 111. FIG. 1 illustrates a sectional side view taken along line 1-1 of FIGS. 1A and 1A shows a top view of the electronic device 100. The electronic device 100 is illustrated in an example three-dimensional space with a first direction X, a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. The electronic device 100 has a molded package structure 108 with laterally opposite first and second sides 101 and 102, respectively, that are spaced apart from one another along the third direction Z. The package structure 108 also has respective third and fourth sides 103 and 104 that are spaced apart from one another along the first direction X, and respective fifth and sixth sides 105 and 106 (FIG. 1A) that are spaced apart from one another along the second direction Y in the illustrated position.

The example electronic device 100 in one example is a chip on lead (COL) configuration with the semiconductor die 110 attached to interior portions of leads 109 by a non-conductive b-stage die attach film adhesive (DAF) 111. In other examples, the semiconductor die 110 can be attached to a dedicated support structure, such as a die attach pad (not shown) of a starting lead frame using pre-formed DAF 111. The example semiconductor die 110 has a thickness T, for example, approximately 100 µm or less, although not a requirement of all possible implementations. The illustrated example has bond wires 112 that form electrical connections between conductive metal terminals (e.g., bond pads) of the semiconductor die 110 and respective ones of the leads 109. In other examples, different forms of electrical connections can be provided, such as flip-chip solder connections (not shown) alone or in combination with bond wires 112. The illustrated compact device 100 has a single semiconductor die 110, although other examples are possible having more than one semiconductor die and/or a die 110 in combination with one or more further components (not shown) at least partially enclosed by the package structure 108.

In one example, the DAF 111 is a b-stage material, such as a non-conductive polymeric epoxy formed on select interior portions of the top sides or surfaces of the leads 109 and partially cured to solidification during lead frame manufacturing. In one implementation, the DAF 111 is a material with two different curing points, which may be cured thermally such as by heating, and/or by ultraviolet (UV) exposure. The dual curing capability facilitates initial curing, for example, at or above a first curing temperature to solidify the DAF material after liquid or semi-liquid formation (e.g., semi-liquid paste DAF formed by screen printing, stencil printing, etc.) on an approximately flat or planar portion of a metal substrate surface. The lead frame can then be completed, including formation of lead frame features on, in and/or through the metal substrate by stamping, etching, etc. while the previously formed and solidified DAF 111 is present to provide a lead frame with DAF 111 already located in select areas designated for eventual die attachment.

The semiconductor die 110 can be subsequently attached to the DAF 111 and then a final cure can be performed (e.g., thermal, UV, etc. at a higher second temperature or exposure energy) to adhere the die 110 to the DAF 111 during integrated circuit packaging processing. Forming the DAF 111 on the metal substrate avoids embedded silicon fragments in the DAF 111 because the DAF 111 is not present on the wafer during wafer dicing. In addition, the preformed DAF 111 cannot induce wafer bowing because the DAF 111 is not applied to a wafer, and the preformed DAF 111 can provide a workable solution for attaching very thin dies in COL or other compact packaged electronic device types.

The example electronic device 100 has indented features 113, which may be referred to as half-etch features that extend into the bottom side or surface of the leads 109. In another implementation, the indented features 113 can be omitted. In one example, the half-etch indented features 113 can be formed before formation of the DAF 111 on the top side of a metal substrate during lead frame manufacturing. In one implementation, the further lead frame features (e.g., openings extending through the metal from the top side to the bottom side) are formed by etching, stamping, etc., after the DAF 111 is formed on the top side of a metal substrate. In another example, the indented features 113 can be formed into the bottom side of the metal substrate after formation of the DAF 111 on the top side.

FIG. 1 illustrates the electronic device 100 in a system installation, such as an automotive system, and industrial system, etc. The system in this example includes a circuit board 130 (e.g., a printed circuit board or PCB). The circuit board 130 has a top side with conductive metal pads 131. The electronic device 100 is mounted to or installed on the circuit board 130 in the illustrated example by solder 132 that forms electrical and mechanical connections of the respective leads 109 to the conductive metal pads 131 of the circuit board 130.

The leads 109 of the electronic device 100 have sidewalls that are approximately flush or co-planar with the respective lateral sides 103-106 and bottoms that are approximately flush with the bottom side 101 of the package structure 108 (e.g., referred to as no-lead shapes), although not a requirement of all possible implementations. In other examples, different lead shapes can be used that extend downward and laterally outward, such as gull-wing leads, j-leads, etc.

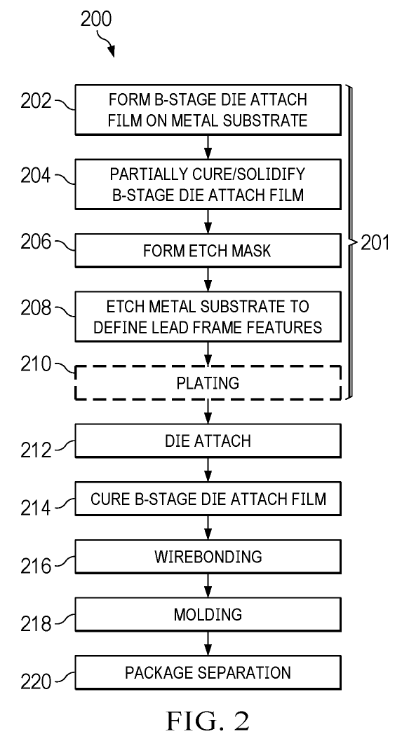

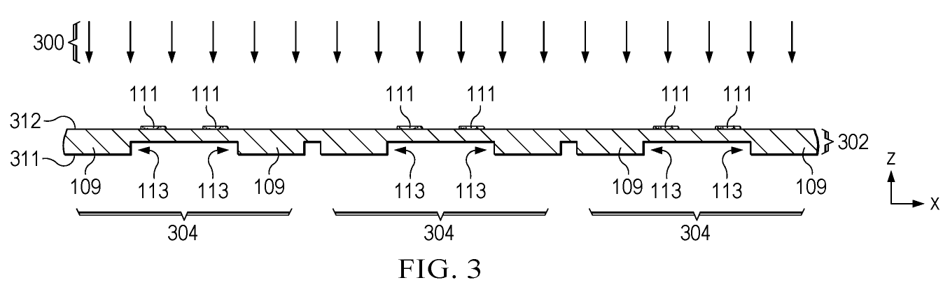

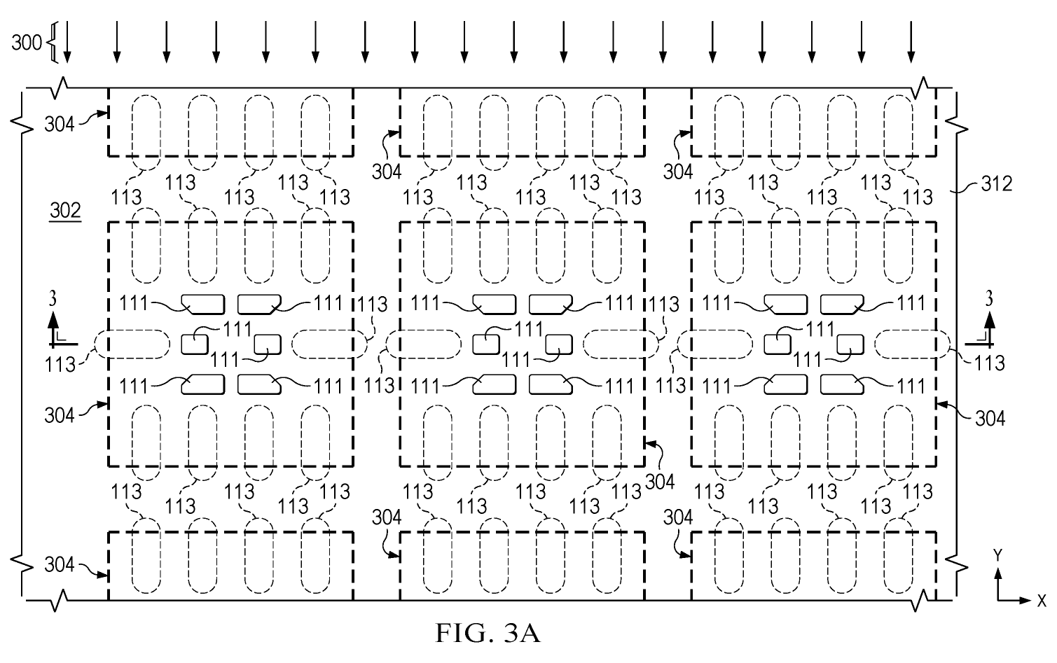

Referring now to FIGS. 2-12, FIG. 2 shows an example method 200 of fabricating an electronic device with an included method 201 for fabricating a lead frame. FIGS. 3-7A show an example lead frame 302 undergoing fabrication processing and FIGS. 3-12 show the electronic device 100 of FIGS. 1 and 1A undergoing fabrication processing according to an implementation of the method 200.

The included lead frame fabrication method 201 in one example includes forming DAF material 111 on the top side of a metal substrate at 202 in FIG. 2. In one implementation, the lead frame fabrication method 201 can include forming the above described indented features 113 (e.g., half-etch indented features) before forming the DAF 111 on the top side of a metal substrate during lead frame manufacturing. The indented features 113, where used, can be formed by any suitable processing techniques and equipment, such as masked etching, stamping, machining, etc. (not shown). In another implementation, indented features 113 can be formed in the bottom side of the metal substrate after forming the DAF 111 on the top side. In further implementations, the indented lead frame features 113 can be omitted.

FIGS. 3 and 3A show one example, in which a die attach film formation process 300 is performed using a metal substrate 302 (which may also be referred to as a lead frame strip or lead frame panel array). The metal substrate 302 has a first or bottom side 311 (FIG. 3) and an opposite second or top side 312. In addition, the example metal substrate 302 has multiple unit areas 304 arranged in an array of rows along the first direction X and columns along the second direction Y, several of which are shown in FIGS. 3 and 3A. The example metal substrate 302 has the previously formed indented features 113 that extend into the first side 311 (e.g., along the third direction Z in FIG. 3). The metal substrate 302 can be any suitable metal material, such as an electrical conductor that is or includes aluminum, copper and their alloys, etc. In the illustrated example, the top or second side 312 of the metal substrate 302 is approximately planar (e.g., flat). Good planarity of the second side 312 can facilitate cost effective and quick formation of liquid or semi-liquid die attach film material in select locations along the second side 312 of the metal substrate 302.

The die attach film formation process 300 forms the DAF 111 on select portions of the metal substrate 302. In the illustrated example, the process 300 forms the DAF 111 along portions of prospective leads 109 in each unit area 304 of the top side 312 of the metal substrate 302. In one example, the die attach film formation process 300 includes stencil printing the DAF 111 on the select portions of the metal substrate 302 in each unit area 304. The process 300 in one example uses a stencil (not shown) that covers portions of the second side 312 with openings corresponding to the locations of the DAF 111 in each unit area 304 as shown in the top view of FIG. 3A. The process 300 in one example includes dispensing the DAF 111 as a liquid or semi-liquid (e.g., paste) polymeric b-stage epoxy into or on the stencil and spreading the DAF 111 using a blade, squeegee or other suitable tool in the stencil to form the DAF 111 along the second side 312 in the stencil openings.

In another example, the die attach film formation process 300 includes screen printing the DAF 111 on the select portions of the metal substrate 302 using a screen (not shown) with a mesh configured to transfer the DAF 111 onto the metal substrate 302 except in areas made impermeable to the DAF 111 by a blocking structure such as an associated stencil. The process 300 in one example includes dispensing the DAF 111 as a liquid or semi-liquid polymeric b-stage epoxy into or on the screen and spreading the DAF 111 using a blade, squeegee or other suitable tool on the screen to form the DAF 111 along the second side 312 in locations corresponding to openings of the silk screen as shown in FIGS. 3 and 3A. The blade or squeegee is translated in a first stroke across the screen to fill the open mesh apertures with the DAF 111 except in areas made impermeable to the DAF 111. The blade or squeegee is then translated in a reverse stroke to cause the screen to touch the desired portions of the second side 312 of the metal substrate 302 along a line of contact. This wets the select portions of the substrate 302 with liquid or semi-liquid DAF material 111, which is pulled out of the mesh apertures as the screen springs back after the blade or squeegee passes.

In one example, the openings of the stencil or permeable portions of the screen mesh are located along approximately planar (e.g., flat) surfaces of the second side 312 of the metal substrate 302, although not a requirement of all possible implementations. In other implementations, different DAF formation processes and equipment can be used to form the DAF 111 on select portions of the second side 312 of the metal substrate 302 in one or more unit areas 314, such as printing or other selective deposition techniques. In other implementations, different DAF materials 111 can be used. The DAF 111 can be formed to any suitable thickness that facilitates subsequent attachment of a semiconductor die 110 to the select portions of the top side 312 of the metal substrate 302, including thickness variations due to one or more intervening curing steps.

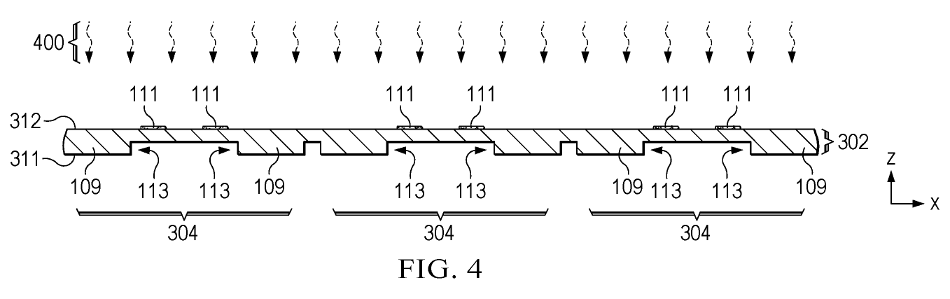

At 204 in FIG. 2, the DAF formation in one example also includes partially curing the DAF 111 to solidify the DAF 111 before forming remaining lead frame features in the metal substrate 302. FIG. 4 shows one example, in which a first curing process 400 is performed that promotes solidification of the DAF 111. In one example, the first curing process 400 is or includes heating the DAF 111 to promote solidification at a first temperature. In another example, the first curing process 400 is or includes exposing the DAF 111 to ultraviolet light (e.g., UV partial curing) to promote solidification of the DAF 111 at a first energy, alone or in combination with heating or other curing processing, sequentially and/or concurrently. In one example, the curing at 204 provides a partially cured DAF 111 on the select portions of the second side 312 of the metal substrate 302, for example, using b-stage DAF material 111 that has two separate curing levels (e.g., at two different curing temperature ranges and/or two separate UV curing energy ranges). The partially cured DAF 111 is configured to be subsequently cured for a second time at a second higher curing temperature and/or UV cured at a second higher energy level, for example, after attachment of the semiconductor die 110. In another example, the first curing at 204 in FIG. 2 can be omitted, for example, where the DAF 111 is formed in a semi-solid or solid form by the processing at 202.

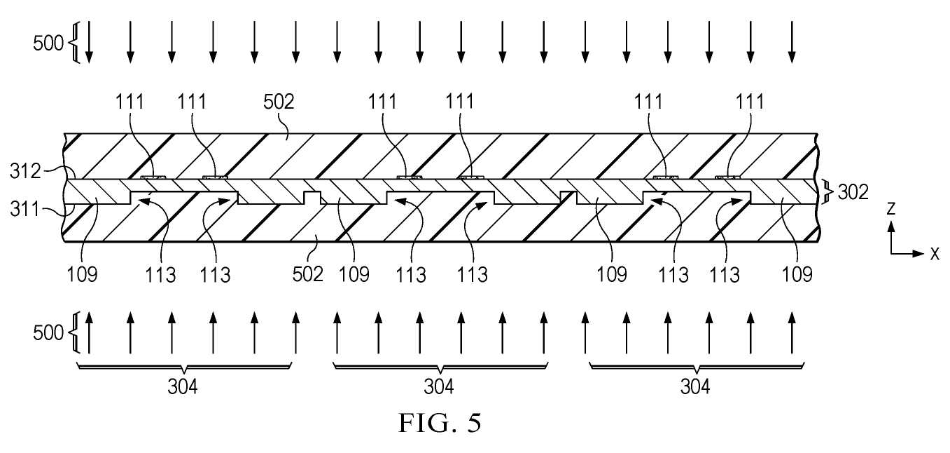

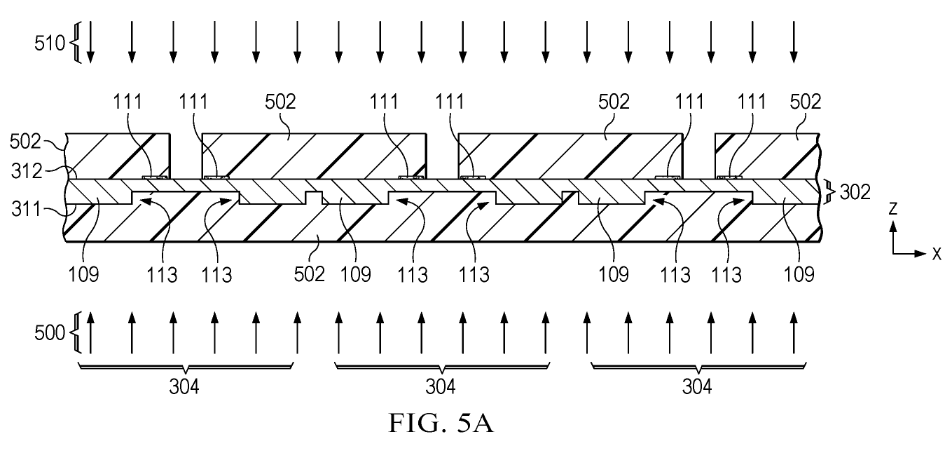

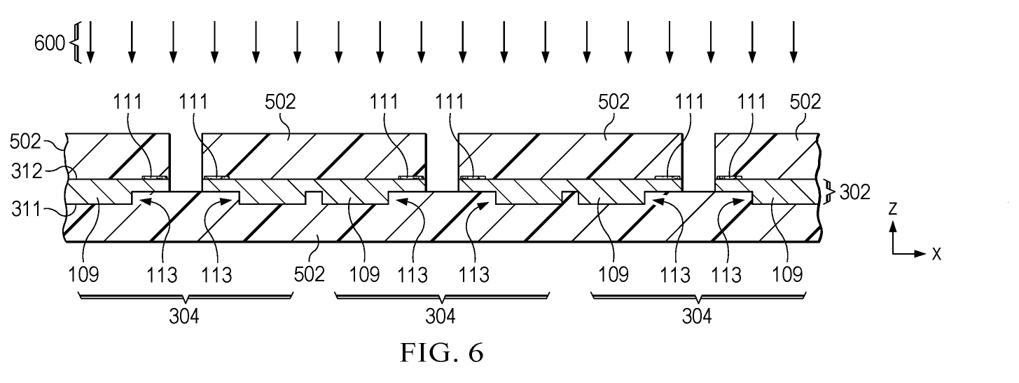

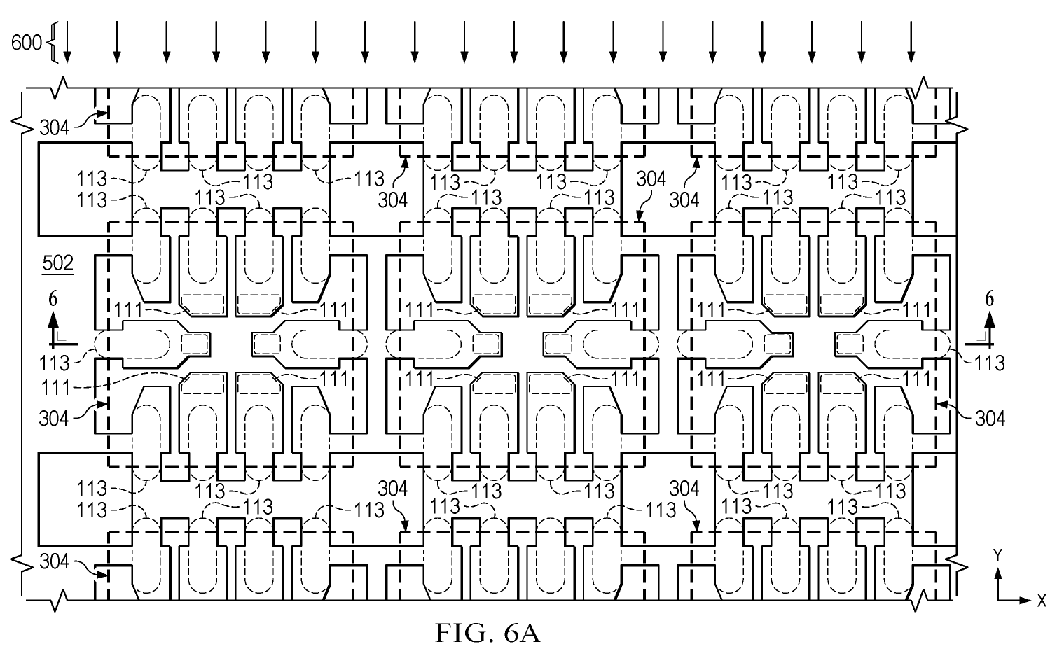

The lead frame fabrication method 201 in FIG. 2 continues at 206 and 208 with forming lead frame features in the metal substrate 302 while the DAF 111 is present. FIGS. 5-6A show one example using masked etching of select portions of the metal substrate 302 that forms openings that extend between the first and second sides 311 and 312. In other examples, different feature formation techniques and tools can be used, for example, chemical etching, laser etching or cutting, stamping, etc.) after the DAF 111 is formed on the top side 312 of the metal substrate 302. In another example, the indented features 113 can be formed into the bottom side 311 of the metal substrate 302 after formation of the DAF 111 on the top side, where top and/or bottom side lead frame features can be formed separately or in a combined process in certain implementations.

At 206 in FIG. 2, the illustrated example includes forming a patterned etch mask at least partially on the DAF 111. FIG. 5 shows one example, in which a deposition process 500 is performed that forms an etch mask layer 502 on the respective first and second sides 311 and 312 of the metal substrate 302. In one example, the mask layer 502 is or includes photoresist or other suitable material that can be patterned and facilitate chemical etch selectivity with respect to etchant selection and the metal material (e.g., copper) of the metal substrate 302 to be etched. In the illustrated example, the bottom side half-etch indented features 113 are filled with and covered by the etch mask layer 502. In one example, the photoresist is applied as a laminate photoresist (also referred to as a dry film resist), which can protect B-stage die attach film 111 during etching.

In FIG. 5A, a patterning process 510 is performed that patterns the etch mask layer 502 with openings along the second side 312 that correspond to the desired locations of the lead frame features to be etched in the metal substrate 302. In the illustrated example, the patterned etch mask 502 covers the previously formed DAF 111, although not a requirement of all possible implementations. In another example, the etch mask can expose all or portions of the previously formed DAF 111, for example, where subsequent etching process is highly selective with respect to the DAF material 111 and the etch processing does not remove significant amounts of the DAF 111.

At 208 in FIG. 2, lead frame features are formed (e.g., openings between the respective first and second sides 311 and 312 of the metal substrate 302), for example, by etching an exposed portion of the metal substrate 302 to form the lead frame features including openings that define leads and other features of the lead frame. FIGS. 6 and 6A show one example, in which an etch process 600 is performed that etches the lead frame features through the openings in the patterned etch mask 502 while the DAF 111 is present. The remaining etch mask material 502 can then be removed. The lead frame feature formation at 206 and 208 provides a metal lead frame 302 with the desired features and the DAF 111 on select portions of the top side 312.

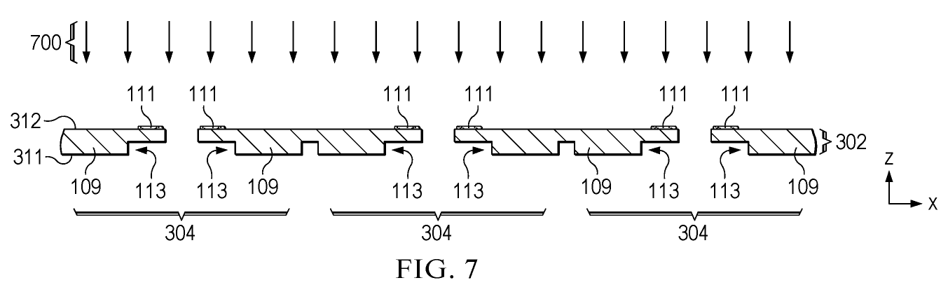

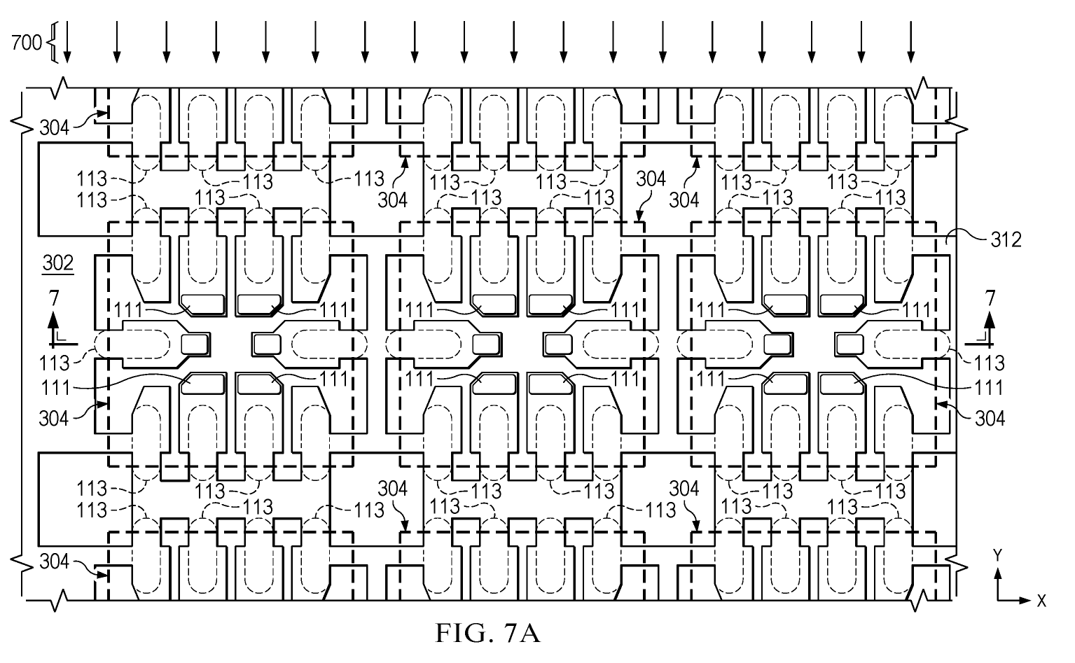

In one example, the lead frame manufacturing method 201 includes optional plating. FIGS. 7 and 7A show one example, in which a plating process 700 is performed that plates exposed surfaces of the metal lead frame 302. In one example, the plating process 700 is an electroplating process that plates a layer of noble metal, such as silver (Ag), nickel palladium gold (NiPdAu), etc. directly on the metal of the substrate 302 or over another plated layer (e.g., tin (Sn), tin-lead (SnPb), etc.) to form a protective plated coating. In another implementation, the plating at 210 can be omitted. Where included, the plated surface can facilitate subsequent solderability of lead features of a manufactured electronic device 100 to a host circuit board (e.g., FIG. 1 above) and can mitigate lead corrosion while the electronic device 100 is stored as well as after installation on a circuit board or into a socket.

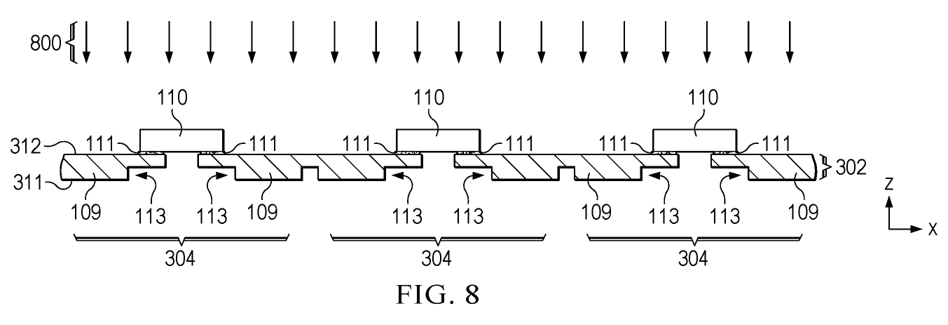

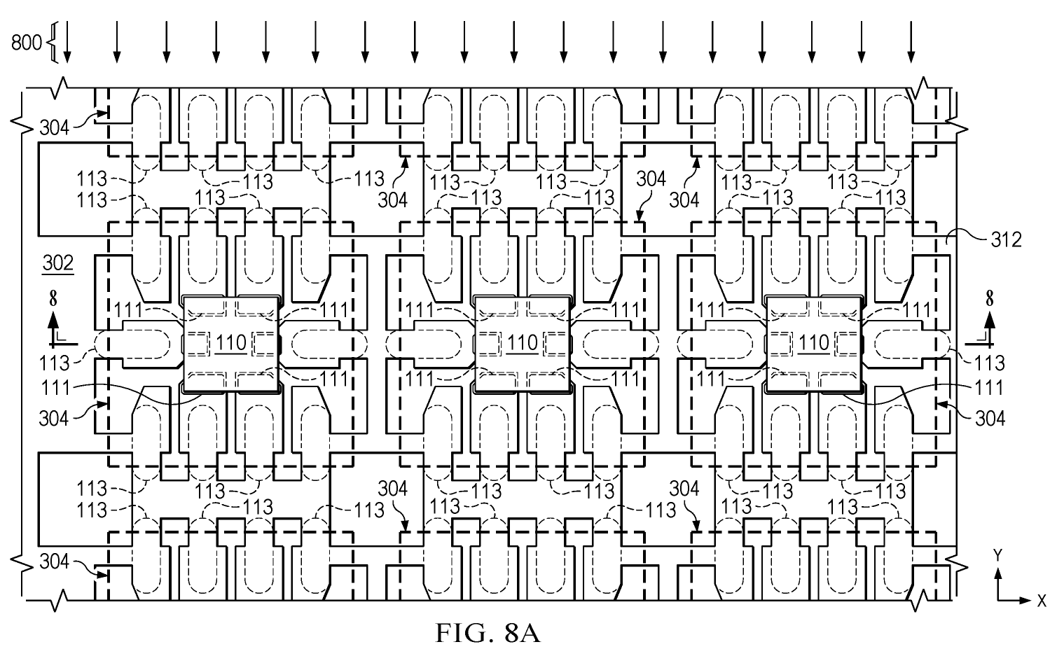

The electronic device fabrication method 200 in FIG. 2 can include the lead frame fabrication method 201 in one continuous process, or the finished lead frame 302 can be used in a separate IC manufacturing process. At 212 in FIG. 2, the method 200 includes die attach processing at 212 to attach an instance of the semiconductor die 110 to a portion of the DAF 111 over the prospective lead 109 of the metal substrate 302 in each unit area 304 of the lead frame 302. FIGS. 8 and 8A show respective partial side and top views of one example, in which a die attach process 800 is performed that attaches an instance of the semiconductor die 110 to the individual unit areas 304 of the lead frame 302 using the previously formed die attach film 111 as an adhesive in the select portions of each unit area 304. The die attach process 800 attaches an instance of the semiconductor die 110 to the previously formed die attach adhesive 111 in each unit area 304, for example, using automated pick and place equipment (not shown).

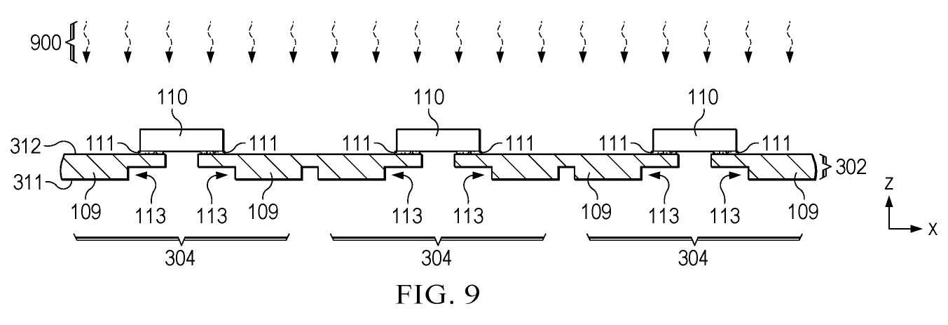

In one implementation, the method 200 includes second or final adhesive curing processing to cure the die attach adhesive 111 at 214 in FIG. 2, such as by thermal heating, UV exposure or other suitable techniques. FIG. 9 shows one example, in which a second thermal curing process 900 is performed that cures the DAF 111. Where a first or initial curing was previously performed (e.g., at 204 in FIG. 2 during lead frame fabrication), the final curing at 214 can be performed at a second (e.g., higher) temperature and/or UV curing can be performed at 214 at a second higher energy. The curing at 214 can promote adhesion of the attached semiconductor die 110 to the lead features of the unit areas 304 by the die attach film (DAF) adhesive 111.

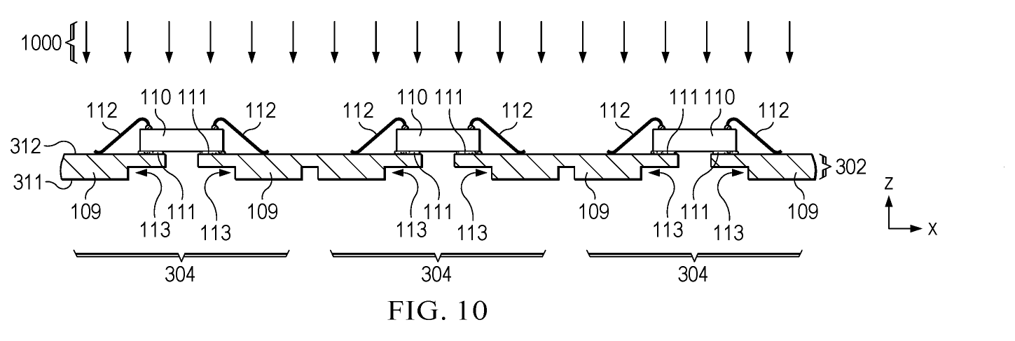

The method 200 continues at 216 in FIG. 2 with electrical coupling to couple the conductive terminals of the semiconductor die 110 to the prospective lead features 109 of the lead frame 302 in each unit area 304. FIG. 10 shows one example, in which a wirebonding process 1000 is performed that electrically couples the semiconductor die 110 to the prospective leads 109 of the unit areas 304 of the lead frame 302. The illustrated process 1000 forms bond wires 112 between respective conductive features or terminals (e.g., bond pads) of the semiconductor die 110 and one of the prospective leads 109 of the unit area 304 of the lead frame 302.

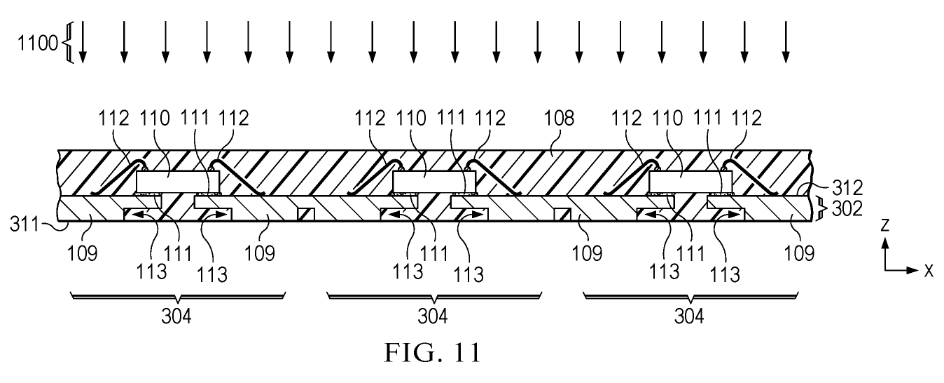

The method 200 continues at 218 in FIG. 2 with molding processing to form the molded package structure 108. FIG. 11 shows one example, in which a molding process 1100 is performed to form the molded package structure 108 that encloses the bond wires 112, the semiconductor die 110 and interior portions of the prospective leads 109 in each unit area 304 of the lead frame 302. In one example, a single mold cavity can be used to form a unitary magnetic molded structure 108 that extends across all the rows and columns of the lead frame panel array structure. In the illustrated implementation, individual mold cavities are used to form respective molded package structures 108 in each unit area, for example, to facilitate lead trimming and forming operations. In another example, individual mold cavities extend across two or more unit areas of the lead frame panel array structure, for example, to form package structures 108 along rows or columns of the array structure.

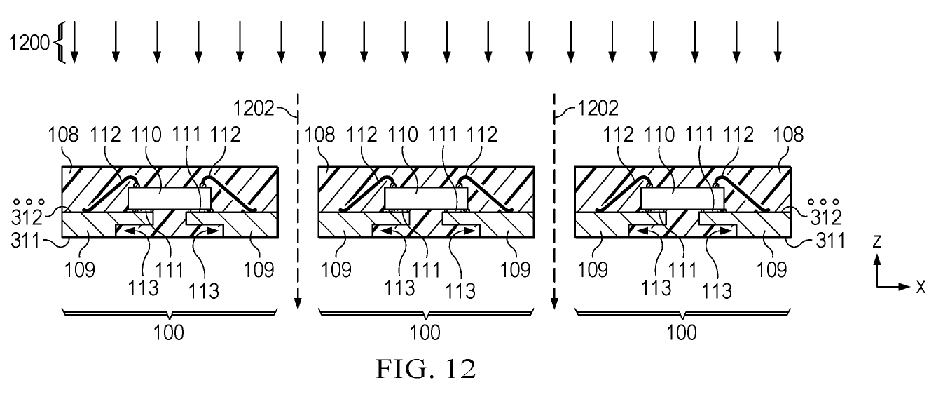

At 220 in FIG. 2, the method 200 includes package separation processing that separates individual semiconductor devices 100 of the respective unit areas 302 from the lead frame 302. FIG. 12 shows one example, in which a package separation process 1200 is performed that separates adjacent packaged electronic devices 100 from one another along columns of the starting lead frame panel array structure 302 to provide separated packaged electronic devices 100 as described above in connection with FIGS. 1 and 1A. In one example, the package separation process 1200 includes saw cutting to separate remaining portions of the lead frame 302 (e.g., tie bars, leads, etc.) from the electronic devices 100 in each unit area 304 along cut lines 1202.

The method 200 in FIG. 2 provides a cost effective solution to produce compact electronic devices 100 with small semiconductor dies 110, including 0.25 mm x 0.25 mm dies for chip on lead (COL) packages and other devices with small form factors. The described examples and variants thereof can mitigate or avoid wafer warpage issues for a very thin wafers and dies (e.g., 100 µm or less), especially when metal coverage is high (>60%) on the die surface because the DAF 111 is not applied at the wafer level. The described method 200 also allows use of saw cutting and/or laser cutting for die singulation without the risk of embedded semiconductor particles (e.g., silicon) in the DAF 111, and avoids challenges associated with alternative plasma dicing approaches. The semiconductor device manufacturing method 200 and the included lead frame fabrication method 201 also allow use of b-stage material or other epoxy-based DAF materials 111 to facilitate improved electronic device reliability with good delamination performance to adhere the semiconductor die 110 to the leads 109. The optional use of b-stage material for the DAF 111 allows initial and final curing (e.g., at 204 and 214 in FIG. 2) with initial screen printing or other formation of the DAF 111 on the metal substrate 302 in liquid or semi-liquid form to facilitate precise DAF location and select portions of the top side 312 and solidification by the initial curing at 204. This provides the lead frame 304 with a robust DAF structure 111 in the desired locations of each unit area 304 to simplify the die attach processing (e.g., at 212 in FIG. 2) and provide a low cost manufacturing process with enhanced process yield through eliminating leakage through embedded silicon chips or debris in the DAF 111. Moreover, the described examples facilitate the use of low cost metal substrates 302, such as copper.

Modifications are possible in the described examples, and other implementations are possible, within the scope of the claims.

What is claimed is:

1. A method, comprising:
forming a die attach film (DAF) on select portions of a metal substrate; and
forming lead frame features in the metal substrate while the DAF is present.

2. The method of claim 1, wherein forming the DAF includes stencil printing the DAF on the select portions of the metal substrate.

3. The method of claim 1, wherein forming the DAF includes screen printing the DAF on the select portions of the metal substrate.

4. The method of claim 1, further comprising partially curing the DAF to solidify the DAF before forming the lead frame features in the metal substrate.

5. The method of claim 4, wherein partially curing the DAF includes heating the DAF.

6. The method of claim 4, wherein partially curing the DAF includes exposing the DAF to ultraviolet light.

7. The method of claim 1, wherein the DAF is a b-stage epoxy.

8. The method of claim 1, further comprising plating a surface of the lead frame features in the metal substrate while the DAF is present.

9. The method of claim 1, wherein the metal substrate includes copper.

10. The method of claim 1, wherein forming the lead frame features in the metal substrate includes:
forming a patterned etch mask at least partially on the DAF; and
etching an exposed portion of the metal substrate to form the lead frame features.

11. The method of claim 1, further comprising:
attaching a semiconductor die to the DAF; and
electrically coupling a terminal of the semiconductor die to a prospective lead of the metal substrate.

12. The method of claim 11, wherein attaching the semiconductor die to the DAF includes attaching the semiconductor die to a portion of the DAF over the prospective lead of the metal substrate.

13. The method of claim 11, wherein electrically coupling the terminal of the semiconductor die to the prospective lead of the metal substrate includes forming a bond wire between the terminal of the semiconductor die and the prospective lead of the metal substrate.

14. The method of claim 11, further comprising:
performing a first curing process to solidify the DAF before forming the lead frame features in the metal substrate; and
performing a second curing process after attaching the semiconductor die to the DAF to promote adhesion of the semiconductor die to the DAF.

15. The method of claim 11, further comprising:
forming a package structure that encloses the semiconductor die and a portion of the prospective lead of the metal substrate; and
separating an electronic device from the metal substrate.

16. A lead frame, comprising:
a metal substrate having opposite first and second sides that extend in respective first and second planes of a first direction and an orthogonal second direction, and openings extending between the first and second sides of the metal substrate in respective unit areas arranged in rows along the first direction and columns along the second direction, the respective unit areas including a prospective lead; and
a die attach film (DAF) extending on select portions of the second side of the metal substrate.

17. The lead frame of claim 16, wherein the DAF is a partially cured B-stage die attach film.

18. The lead frame of claim 16, wherein the metal substrate includes copper.

19. The lead frame of claim 16, wherein the die attach film (DAF) extends on the prospective lead in each respective unit area.

20. The lead frame of claim 16, wherein the metal substrate includes a plated surface.
